(19) United States
(12) Patent Application Publication
(10) Pub. No.: US 2024/0300068 A1
(43) Pub. Date: Sep. 12, 2024

(54) POLISHING APPARATUS AND POLISHING METHOD

(71) Applicant: EBARA CORPORATION, Tokyo (JP)

(72) Inventors: Hiroto YAMADA, Tokyo (JP); Taro TAKAHASHI, Tokyo (JP)

(21) Appl. No.: 18/589,145

(22) Filed: Feb. 27, 2024

(30) Foreign Application Priority Data
Mar. 7, 2023 (JP) 2023-034763

(51) Int. Cl. B24B 49/04; B24B 49/10; B24B 49/16

(52) U.S. Cl. CPC B24B 49/04; B24B 49/105; B24B 49/16

(57) ABSTRACT

A polishing apparatus includes a polishing table with a polishing pad for polishing a film formed on a semiconductor wafer. The polishing apparatus includes a first sensor that outputs a first signal corresponding to the film thickness of the film and a second sensor that is more sensitive than the first sensor and that outputs a second signal corresponding to the film thickness of the film. When the film thickness of the film is equal to or less than a predetermined film thickness, the film thickness detector detects the film thickness of the film according to a second signal. When the film is thicker than the predetermined film thickness, the film thickness detector detects the film thickness of the film according to the first signal and the second signal.

### CROSS REFERENCE TO RELATED APPLICATION

This application claims priority to Japanese Patent Application No. 2023-034763 filed Mar. 7, 2023, the entire contents of which are hereby incorporated by reference.

### TECHNICAL FIELD

The present invention relates to a polishing apparatus and a polishing method.

### BACKGROUND ART

In the manufacturing of semiconductor devices, it has been a practice to planarize semiconductor wafer surfaces. As a means of planarization, chemical mechanical polishing is performed using a polishing apparatus. The chemical mechanical polishing (hereinafter referred to as “CMP”) is a technique of increasing mechanical polishing (surface removal) effects of relative motion between abrasives and an object to be polished through surface-chemistry action held in the abrasives (abrasive grains) themselves or action of chemical components contained in the polishing solution to thereby obtain fast and smooth polished surfaces.

In the polishing apparatus, it has been a practice to detect an optimal polishing end point by using, for example, an eddy current sensor. With the miniaturization of semiconductors, there is a demand for controlling film thicknesses and wiring heights during CMP in progress. In a conventional metal film removal process, film thickness is monitored from the beginning of polishing by using a single sensor in general until a metal film across the wafer surface is removed completely (this state is referred to as “cleared”). A measurement range by the single sensor is adjusted to be wider so as to allow such monitoring. In the cleared state, a metal wiring pattern lying beneath the metal film appears on the surface. The sensor diameter is preferably small to improve resolution in the horizontal direction of the wafer.

When the range is widened, the metal film becomes thinner as polishing of the metal film advances and the sensor output decreases. In other words, sensitivity (resolution in the vertical direction) with respect to the film thickness decreases. Therefore, the situation may be such that the metal film is removed completely or wafer monitoring after clearing the metal film has been difficult. This is because a metal volume of a metal wiring pattern or the like is small. If a small sensor is used to improve the resolution in the horizontal direction, the area of the wafer surface through which the sensor passes (referred to as a “monitoring area”) decreases. Since the sensor passes through a specific part within the wafer surface, the area through which the sensor does not pass increases. For this reason, partial thin film residues may have been generated in the areas through which the sensor does not pass, and even if the sensor detects a polishing end, such remnants (residues) of the thin film may not be detected.

An embodiment of the present invention has been implemented to solve the above-described problems and it is an object of the present invention to provide a polishing apparatus and a polishing method that can reduce thin film remnants (residues).

### SUMMARY OF INVENTION

To solve the above-described problems, a first embodiment of the present invention adopts a configuration of a polishing apparatus including a polishing table with a polishing pad for polishing a film formed on a substrate, a holder configured to hold the substrate and press the substrate against the polishing pad, a first sensor that outputs a first signal according to film thickness of the film, a second sensor that is more sensitive than the first sensor and that outputs a second signal corresponding to film thickness of the film, and a film thickness detector that detects, when the film thickness is equal to or smaller than a predetermined film thickness, the film thickness of the film according to the second signal and detects, when the film thickness is equal to or larger than the predetermined film thickness, the film thickness of the film according to the first signal and the second signal.

In a second embodiment, the film thickness detector adopts a configuration of the polishing apparatus according to the first embodiment of detecting the film thickness of the film according to the second signal when the film thickness detected by the first signal falls below the predetermined film thickness.

A third embodiment adopts the configuration of the polishing apparatus according to the first or second embodiment, in which the second sensor is an eddy current sensor and when film thickness of the film falls below the predetermined film thickness, output of the second signal is equal to or below a saturation level.

A fourth embodiment adopts the configuration of the polishing apparatus according to the third embodiment, in which the first sensor is an eddy current sensor and the first sensor is smaller in size than the second sensor.

A fifth embodiment adopts the configuration of the polishing apparatus according to the third or fourth embodiment, in which a magnetic field generated by the second sensor is stronger than the magnetic field generated by the first sensor.

A sixth embodiment adopts the configuration of the polishing apparatus according to any one of the first to fifth embodiments, in which the polishing apparatus includes a plurality of the first sensors, and/or a plurality of the second sensors.

A seventh embodiment adopts the configuration of the polishing apparatus according to any one of the first to sixth embodiments, in which the first sensor and the second sensor are arranged on the circumference of substantially one circle inside the polishing table.

An eighth embodiment adopts the configuration of the polishing apparatus according to the seventh embodiment, in which there are a plurality of the first sensors, the first sensors are arranged on the circumference at mutually and substantially equal intervals and/or there are a plurality of the second sensors and the second sensors are arranged at mutually and substantially equal intervals on the circumference.

A ninth embodiment adopts the configuration of the polishing apparatus according to the seventh or eighth embodiment, in which the number of the first sensors is equal to the number of the second sensors, and the first sensors and the second sensors are arranged alternately on the circumference.

A tenth embodiment adopts a configuration of a polishing method, the method including the steps of a holder pressing a substrate against a polishing pad and polishing a film provided on the substrate, a first sensor outputting a first signal corresponding to the film thickness of the film, a second sensor that is more sensitive than the first sensor, outputting a second signal corresponding to the film thickness of the film, a film thickness detector detecting the film thickness of the film according to the first signal and the second signal before the film reaches a predetermined film thickness and detecting the film thickness of the film according to the second signal when the film thickness detector detects that the film falls below the predetermined film thickness.

An eleventh embodiment adopts the configuration of the polishing method according to the tenth embodiment, the method including the steps of a controller controlling pressures in a plurality of pressure chambers provided in the holder according to the film thickness detected by the film thickness detector, the holder pressing the substrate against the polishing pad in a condition in which the pressures in the plurality of pressure chambers are controlled and polishing the film provided on the substrate.

### BRIEF DESCRIPTION OF DRAWINGS

FIG. 1 is a schematic diagram illustrating an overall configuration of a polishing apparatus according to an embodiment of the present invention;

FIG. 2A is a block diagram illustrating a configuration of an eddy current sensor;

FIG. 2B is an equivalent circuit diagram of the eddy current sensor;

FIG. 3 is a schematic diagram illustrating a configuration example of the eddy current sensor according to an embodiment of the present invention;

FIG. 4 is a schematic diagram illustrating a configuration example of the eddy current sensor according to an embodiment of the present invention;

FIG. 5A is a diagram illustrating a conventional sensor arrangement.

FIG. 5B is a diagram illustrating a sensor arrangement according to the embodiment of the present invention;

FIG. 6A is a diagram illustrating film thickness measurement results by the first sensor in FIG. 5A;

FIG. 6B is a diagram illustrating film thickness measurement results by the first sensor in FIG. 5A;

FIG. 7A is a diagram illustrating film thickness measurement results by the first sensor and the second sensor in FIG. 5B;

FIG. 7B is a diagram illustrating film thickness measurement results by the first sensor and the second sensor in FIG. 5B;

FIG. 8A is a diagram illustrating an enlarged display of a film thickness distribution measured by the second sensor;

FIG. 8B is a diagram illustrating an enlarged display of a film thickness distribution measured by the second sensor;

FIG. 8C is a diagram illustrating an enlarged display of a film thickness distribution measured by the second sensor;

FIG. 9 is a diagram illustrating a flowchart of a polishing process;

FIG. 10 is a diagram illustrating a flowchart of a polishing process;

FIG. 11A is a diagram illustrating sensor traces;

FIG. 11B is a diagram illustrating sensor traces;

FIG. 12A is a diagram illustrating film thickness measurement results by the first sensor and the second sensor in FIG. 5B;

FIG. 12B is a diagram illustrating film thickness measurement results by the first sensor and the second sensor in FIG. 5B;

FIG. 13A is a diagram illustrating an enlarged display of a film thickness distribution measured by the second sensor;

FIG. 13B is a diagram illustrating an enlarged display of a film thickness distribution measured by the second sensor;

FIG. 13C is a diagram illustrating an enlarged display of a film thickness distribution measured by the second sensor;

FIG. 13D is a diagram illustrating an enlarged display of a film thickness distribution measured by the second sensor;

FIG. 13E is a diagram illustrating an enlarged display of a film thickness distribution measured by the second sensor;

FIG. 13F is a diagram illustrating an enlarged display of a film thickness distribution measured by the second sensor;

FIG. 14 is a diagram illustrating a flowchart of a polishing process;

FIG. 15 is a diagram illustrating a control example of an airbag (pressure chamber);

FIG. 16A is a diagram illustrating monitoring of polishing abnormality by the second sensor;

FIG. 16B is a diagram illustrating monitoring of polishing abnormality by the second sensor;

FIG. 16C is a diagram illustrating monitoring of polishing abnormality by the second sensor;

FIG. 17 is a diagram illustrating an example of film thickness measurement results of one semiconductor wafer by the second sensor after a polishing end displayed on a monitor;

FIG. 18A is a diagram illustrating differences between the embodiment of the present invention shown in FIG. 7 and a comparative example; and

FIG. 18B is a diagram illustrating differences between the embodiment of the present invention shown in FIG. 7 and a comparative example; and

FIG. 18C is a diagram illustrating differences between the embodiment of the present invention shown in FIG. 7 and a comparative example; and

FIG. 18D is a diagram illustrating differences between the embodiment of the present invention shown in FIG. 7 and a comparative example; and

FIG. 18E is a diagram illustrating differences between the embodiment of the present invention shown in FIG. 7 and a comparative example; and

FIG. 19A is a diagram illustrating a sensor arrangement within a polishing table when at least one of the first sensor and the second sensor is plural.

FIG. 19B is a diagram illustrating a sensor arrangement within a polishing table when at least one of the first sensor and the second sensor is plural.

### DESCRIPTION OF EMBODIMENTS

Hereinafter, embodiments of the present invention will be described with reference to the accompanying drawings. Note that in the following embodiments, identical reference numerals are assigned to identical or equivalent members and duplicate descriptions may be omitted. Moreover, features pointed out in the respective embodiments are also applicable to other embodiments as long as those features do not contradict each other.

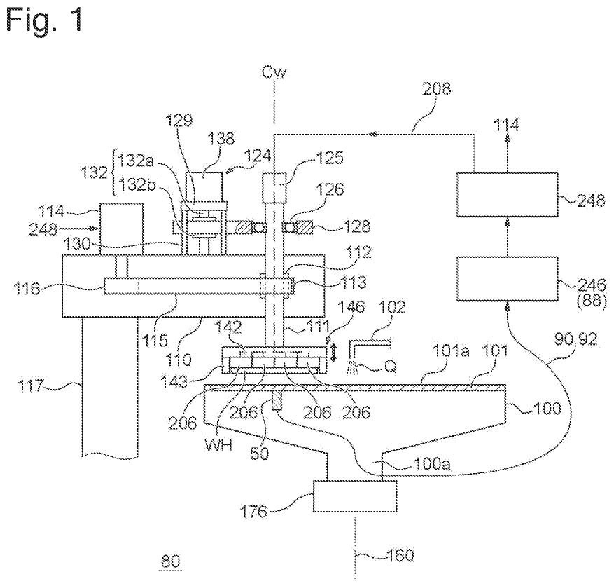

FIG. 1 is a schematic diagram illustrating an overall configuration of a polishing apparatus 80 according to an embodiment of the present invention. As shown in FIG. 1, the polishing apparatus 80 is provided with a polishing table 100 configured to have a polishing pad 101 to polish a substrate including a conductor affixed thereto, a motor 176 (table driver) configured to drive and rotate the polishing table 100, a top ring (holder) 146 configured to hold the substrate to be polished, such as a semiconductor wafer WH and press the substrate against the polishing pad 101, an eddy current sensor 50 arranged inside the polishing table 100 configured to detect an eddy current formed on the conductor as the polishing table 100 rotates and an end point detection controller 246 (film thickness detector 88) configured to calculate film thickness data of the conductor from the detected eddy current. The polishing pad 101 polishes the film formed on the semiconductor wafer WH.

As will be described later, a plurality of sensors (a first sensor 500 and a second sensor 502) are mounted on the polishing table of the polishing apparatus 80. Hereinafter, when items common to the plurality of sensors are described, the first sensor 500 and the second sensor 502 are referred to as the “eddy current sensor 50” whereas when items varying among the plurality of sensors are described, the first sensor 500 and the second sensor 502 will be called separately. For simplicity of the drawing in FIG. 1, only one eddy current sensor 50 is described. A specific arrangement of the plurality of sensors will be described later.

The polishing table 100 is coupled with the motor 176, which is a driver disposed below the polishing table via a table shaft 100a and is rotatable around the table shaft 100a. The polishing pad 101 is affixed to a top surface of the polishing table 100 and a surface 101a of the polishing pad 101 constitutes a polishing surface to polish the semiconductor wafer WH or the film formed on the semiconductor wafer WH. A polishing solution supply nozzle 102 is disposed above the polishing table 100 and the polishing solution supply nozzle 102 is configured to supply a polishing solution Q onto the polishing pad 101 above the polishing table 100. As shown in FIG. 1, the eddy current sensor 50 is buried inside the polishing table 100.

The top ring 146 is basically composed of a top ring body 142 to press the semiconductor wafer WH against the polishing surface 101a and a retainer ring 143 configured to hold an outer edge of the semiconductor wafer WH to prevent the semiconductor wafer WH from flying out of the top ring.

The top ring 146 is connected to a top ring shaft 111 and this top ring shaft 111 is configured to move up and down with respect to a top ring head 110 by a vertical motion mechanism 124. The vertical motion of the top ring shaft 111 is configured to cause the entire top ring 146 to move up and down with respect to the top ring head 110 to position the top ring. Note that a rotary joint 125 is attached to the top end of the top ring shaft 111.

The vertical motion mechanism 124 that causes the top ring shaft 111 and the top ring 146 to move up and down is provided with a bridge 128 that rotatably supports the top ring shaft 111 via a bearing 126, a ball screw 132 attached to the bridge 128, a support stand 129 supported by a pillar 130 and an AC servo motor 138 provided on a support stand 129. The support stand 129 that supports the servo motor 138 is fixed to the top ring head 110 via the pillar 130.

The ball screw 132 is provided with a screw axis 132a coupled with the servo motor 138 and a nut 132b into which the screw axis 132a is screwed. The top ring shaft 111 is configured to move up and down in unison with the bridge 128. Therefore, when the servo motor 138 is driven, the bridge 128 moves up and down via the ball screw 132, which causes the top ring shaft 111 and the top ring 146 to move up and down.

The top ring shaft 111 is coupled with a pivoted cylinder 112 via a key (not shown). The pivoted cylinder 112 is provided with a timing pulley 113 at its peripheral portion. A top ring motor 114 is fixed to the top ring head 110 and the timing pulley 113 is connected to a timing pulley 116 provided in the top ring motor 114 via a timing belt 115. Therefore, rotating and driving the top ring motor 114 causes the pivoted cylinder 112 and the top ring shaft 111 to rotate in unison via the timing pulley 116, the timing belt 115 and the timing pulley 113, and causes the top ring 146 to rotate. Note that the top ring head 110 is supported by a top ring head shaft 117 rotatably supported by a frame (not shown).

The top ring 146 of the polishing apparatus configured as shown in FIG. 1 is enabled to hold a substrate such as a semiconductor wafer WH on its undersurface. The top ring head 110 is configured to be rotatable around the top ring head shaft 117 as the center and the top ring 146 holding the semiconductor wafer WH on its undersurface is moved from a semiconductor wafer WH receiving position to above the polishing table 100 as the top ring head 110 rotates. The top ring 146 is then caused to descend and the semiconductor wafer WH is pressed against the surface (polishing surface) 101a of the polishing pad 101. At this time, the top ring 146 and the polishing table 100 are respectively rotated and a polishing solution is supplied from the polishing solution supply nozzle 102 provided above the polishing table 100 onto the polishing pad 101. Thus, the surface of the semiconductor wafer WH is polished by sliding the semiconductor wafer WH into contact with the polishing surface 101a of the polishing pad 101.

FIG. 1 illustrates a relationship between the polishing table 100, the eddy current sensor 50 and the semiconductor wafer WH. As shown in FIG. 1, the eddy current sensor 50 is set at a position passing through a center Cw of the semiconductor wafer WH being polished and held onto the top ring 146. The polishing table 100 rotates around a center of rotation 160. For example, while passing below the semiconductor wafer WH, the eddy current sensor 50 is enabled to continuously detect a metal film (conductive film) such as a Cu layer of the semiconductor wafer WH on a trajectory (scan line).

In the present embodiment, a plurality of sensors with different monitored objects are mounted on the polishing table of the polishing apparatus 80 and conditions of a wafer being polished and having a wiring pattern are monitored. Here, “sensors with different monitored objects” mainly means that sensors have different film thickness ranges covered by monitoring. The polishing apparatus 80 includes a film thickness detector 88 (end point detection controller 246) and the polishing apparatus 80 is provided with a first sensor 500 that outputs a first signal 90 corresponding to film thickness of the film formed on the semiconductor wafer WH (substrate) and a second sensor 502 more sensitive than the first sensor 500 that outputs a second signal 92 corresponding to the film thickness. The polishing apparatus 80 is further provided with a film thickness detector 88 that detects film thickness of the film according to the second signal 92 when the film has a predetermined film thickness or less. The first sensor 500 and the second sensor 502 are provided independently of each other. When the film is thicker than the predetermined film thickness, the film thickness detector 88 detects film thickness of the film according to the first signal and the second signal.

In the present embodiment, the polishing apparatus uses a plurality of sensors of varying sensitivity (that is, sensors with different monitored objects). The plurality of sensors of varying sensitivity can monitor a polishing condition of a film having a small metal volume such as a thin film or a wiring pattern during polishing. This makes it possible to provide a polishing apparatus that can reduce thin film remnants (residues).

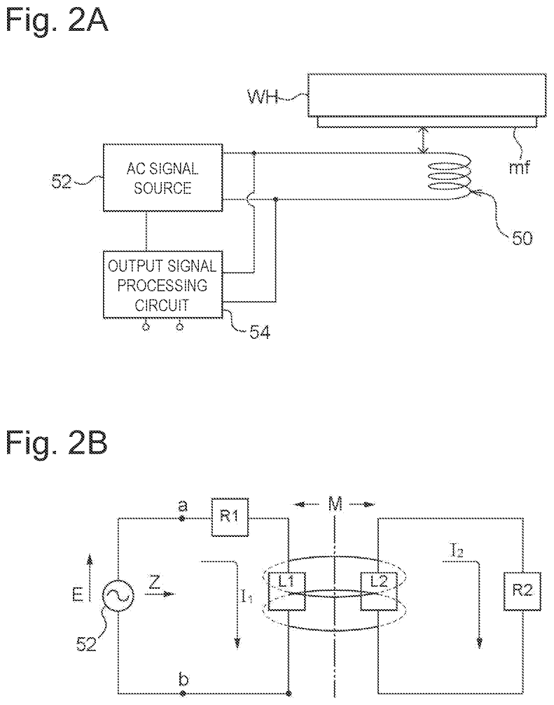

Next, the eddy current sensor 50 (first sensor 500) provided in the polishing apparatus according to the present invention will be described in detail using the accompanying drawings. FIG. 2 is a diagram illustrating a configuration of the eddy current sensor 50, FIG. 2A is a block diagram illustrating a configuration of the eddy current sensor 50 and FIG. 2B is an equivalent circuit diagram of the eddy current sensor 50.

As shown in FIG. 2, the eddy current sensor 50 is disposed in the vicinity of a metal film (or conductive film) mf that is subjected to detection, and an AC signal source 52 is connected to its coil. Here, the metal film (or conductive film) mf that is subjected to detection, is a thin film such as Cu, Al, Au, W formed, for example, on the semiconductor wafer WH. The eddy current sensor 50 is arranged in the vicinity of, for example, 1.0 to 4.0 mm relative to the metal film (or conductive film) that is subjected to detection.

The eddy current sensor 50 is classified into two types: a frequency type to detect the metal film (or conductive film) from a change in oscillation frequency caused by the occurrence of an eddy current in the metal film (or conductive film) mf; and an impedance type to detect the metal film (or conductive film) from a change in impedance. That is, in the frequency type, an eddy current I₂ changes in the equivalent circuit shown in FIG. 2, an impedance Z changes and when the oscillation frequency of the signal source (variable frequency oscillator) 52 changes, the output signal processing circuit 54 (included in the end point detection controller 246) detects a change in the oscillation frequency, and it is possible to detect a change in the metal film (or conductive film). In the impedance type, the eddy current I₂ changes in the equivalent circuit shown in FIG. 2B, the impedance Z changes, and when the impedance Z seen from the signal source (fixed frequency oscillator) 52 changes, the output signal processing circuit 54 detects the change in the impedance Z, and the change in the metal film (or conductive film) can be detected. The output signal processing circuit 54 changes the impedance Z by coherent detection.

The impedance type eddy current sensor extracts signal outputs X and Y, phases, joint impedance Z as will be described later. Measurement information of the metal film (or conductive film) Cu, Al, Au, W is obtained from the frequency F or impedances X and Y or the like. The eddy current sensor 50 can be incorporated at positions in the neighborhood of the inner surface of the polishing table 100 as shown in FIG. 1, and it is possible to dispose the eddy current sensor 50 so as to face the semiconductor wafer to be polished via the polishing pad and detect a change in the metal film (or conductive film) from the eddy current flowing into the metal film (or conductive film) on the semiconductor wafer.

Hereinafter, the impedance type eddy current sensor will be described more specifically. The AC signal source 52 is an oscillator with a fixed frequency on the order of 2 to 30 MHz, and, for example, a crystal oscillator is used. The AC voltage supplied by the AC signal source 52 causes a current I₁ to flow into the eddy current sensor 50. With a current flowing into the eddy current sensor 50 arranged in the vicinity of the metal film (or conductive film) mf, this magnetic flux interlocks with the metal film (or conductive film) mf and a mutual inductance M is thereby formed in between and an eddy current I₂ flows into the metal film (or conductive film) mf. Here, R1 is an equivalent resistor on the primary side including the eddy current sensor, and L₁ is likewise a self-inductance on the primary side including the eddy current sensor. On the metal film (or conductive film) mf side, R2 is an equivalent resistor corresponding to an eddy current loss and L₂ is its self-inductance. The impedance Z viewed from terminals a and b of the AC signal source 52 to the eddy current sensor side changes depending on the scale of the eddy current loss formed in the metal film (or conductive film) mf.

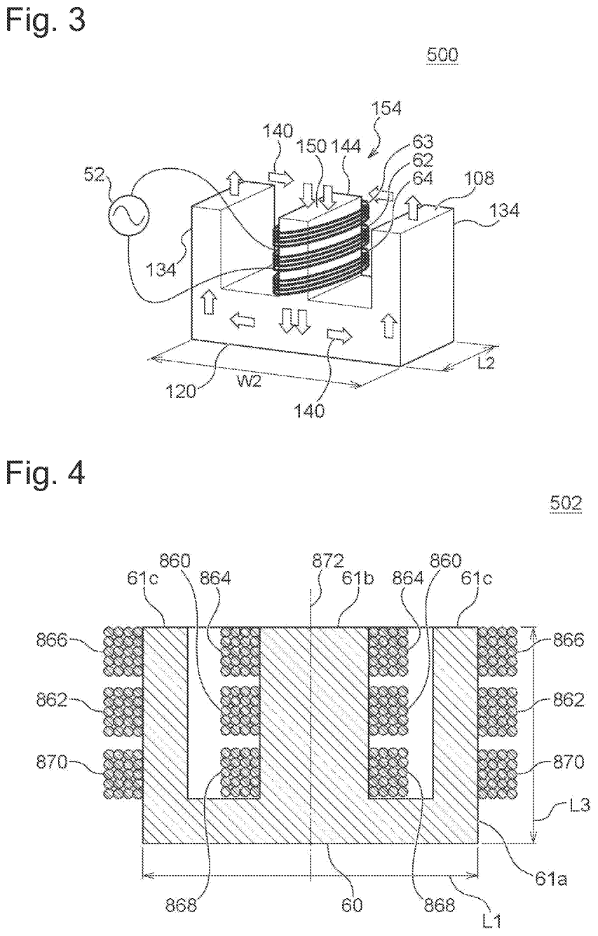

FIG. 3 is a diagram illustrating the first sensor 500 according to the present embodiment. FIG. 3 is a schematic diagram illustrating a configuration of the first sensor 500 according to an embodiment of the present invention. The first sensor 500 to detect an eddy current that can be generated in the conductor includes a core which is a magnetic body including a base 120, a center wall 144 provided on the base 120 in the center of a first direction (direction of an arrow W2) of the base 120 and two end walls 134 provided on the base 120 at both ends of the first direction 122 of the base 120. The two end walls 134 face each other. The core is an E type core. Note that the first sensor 500 is not limited to the sensor in FIG. 3, but may be cylindrical type, substrate type, solenoid type or the like.

The first sensor 500 includes an excitation coil 62 arranged on the center wall 144 capable of generating an eddy current in the conductor, a detection coil 63 placed on the center wall 144 to detect an eddy current and a dummy coil 64 arranged on the center wall 144 to extract an eddy current.

A thick arrow 140 shown in FIG. 3 illustrates a magnetic flux generated by the excitation coil 62. The magnetic flux illustrated by an arrow 140 flows inside the core, from the center wall 144 through the base 120 toward the end wall 134 or flows from the end wall 134 through the base 120 toward the center wall 144. The magnetic flux illustrated by the arrow 140 flows outside the core, from the end wall 134 through the space toward the center wall 144 or flows from the center wall 144 through the space toward the end wall 134.

Of the three coils, the detection coil 63 and the dummy coil 64 constitute a series circuit and both ends of which are connected to a resistor bridge circuit (not shown) including the variable resistor. By performing balance adjustment with the resistor bridge circuit, it is possible to adjust a zero point so that the output of the resistor bridge circuit becomes zero when the film thickness is zero. The output (the first signal 90) of the resistor bridge circuit is inputted to the coherent detection circuit (existing in the end point detection controller 246). The coherent detection circuit extracts a resistor component (R), a reactance component (X), an amplitude output (Z) and a phase output (tan⁻¹ R/X) associated with a film thickness change from the inputted signal. Note that although the resistor bridge circuit is used in the present embodiment, the resistor bridge circuit is not necessarily required.

FIG. 4 is a schematic diagram illustrating a configuration example of the eddy current sensor 50 (second sensor 502) according to an embodiment of the present invention. The second sensor 502 disposed in the vicinity of the substrate in which a conductive film is formed is composed of a pot core 60 and six coils 860, 862, 864, 866, 868 and 870. The pot core 60 which is a magnetic body includes a bottom surface part 61a (base part magnetic body), a magnetic core part 61b (center magnetic body) provided in the center of the bottom surface part 61a, and a circumferential wall part 61c (peripheral part magnetic body) provided in a peripheral part of the bottom surface part 61a. The circumferential wall part 61c is a wall part provided on a peripheral part of the bottom surface part 61a so as to surround the magnetic core part 61b. In the present embodiment, the bottom surface part 61a is a circular disk shape, the magnetic core part 61b is a solid cylindrical shape and the circumferential wall part 61c is a cylinder shape surrounding the bottom surface part 61a.

Of the six coils 860, 862, 864, 866, 868 and 870, the coils 860 and 862 in the center are excitation coils connected to the AC signal source 52. The excitation coils 860 and 862 form an eddy current on the metal film (or conductive film) mf on the semiconductor wafer WH arranged in the vicinity by the magnetic field formed by a voltage supplied from the AC signal source 52. The detection coils 864 and 866 are arranged on the metal film side of the excitation coils 860 and 862 to detect a magnetic field generated by the eddy current formed on the metal film. The dummy coils 868 and 870 are arranged on the opposite side of the detection coils 864 and 866 across the excitation coils 860 and 862.

An excitation coil 860 is arranged on the periphery of the magnetic core part 61b, and is an inner coil that can generate a magnetic field and forms an eddy current on the conductive film. The excitation coil 862 is disposed on the periphery of the circumferential wall part 61c, is an external coil that can generate a magnetic field and forms an eddy current on the conductive film. The detection coil 864 is arranged on the periphery of the magnetic core part 61b, can detect a magnetic field and detects an eddy current formed on the conductive film. The detection coil 866 is arranged on the periphery of the circumferential wall part 61c, can detect a magnetic field and detects an eddy current formed on the conductive film.

The second sensor 502 includes the dummy coils 868 and 870 to detect an eddy current formed on the conductive film. The dummy coil 868 is arranged on the periphery of the magnetic core part 61b and can detect a magnetic field. The dummy coil 870 is arranged on the periphery of the circumferential wall part 61c and can detect a magnetic field. The detection coil and the dummy coil are arranged on the periphery of the magnetic core part 61b and on the periphery of circumferential wall part 61c or on the periphery of the circumferential wall part 61c according to the present embodiment. However, the detection coil and the dummy coil may be arranged either on the periphery of the magnetic core part 61b or on the periphery of the circumferential wall part 61c.

The axial direction of the magnetic core part 61b is orthogonal to the conductive film on the substrate and the detection coils 864 and 866, the excitation coils 860 and 862 and the dummy coils 868 and 870 are arranged at different positions in the axial direction of the magnetic core part 61b and the detection coils 864 and 866, the excitation coils 860 and 862, and the dummy coils 868 and 870 are arranged in order in the axial direction of the magnetic core part 61b from a position near the conductive film on the substrate toward a position far from the conductive film. Lead wires (not shown) extend from the detection coils 864 and 866, the excitation coils 860 and 862, and the dummy coils 868 and 870 respectively to connect external parts.

FIG. 4 is a cross-sectional view in a plane through the central axis 872 of the magnetic core part 61b. The pot core 60 which is a magnetic body includes the bottom surface part 61a in a disk shape, the magnetic core part 61b in a cylindrical shape provided in the center of the bottom surface part 61a and the circumferential wall part 61c in a cylindrical shape provided around the bottom surface part 61a. As one example of dimensions of the pot core 60, a diameter L1 of the bottom surface part 61a is approximately 1 cm to 5 cm, a height L2 of the second sensor 502 is approximately 1 cm to 5 cm. Although the outer diameter of the circumferential wall part 61c has a cylindrical shape identical in the height direction in FIG. 4, it may be a tapered shape that tapers in the direction away from the bottom surface part 61a, that is, tapering toward the distal end.

Lead wires used for the detection coils 864 and 866, the excitation coils 860 and 862 and the dummy coils 868 and 870 are copper, manganin wire, or nichrome wire. Using the manganin wire or nichrome wire minimizes temperature variations in electric resistance or the like, and improves temperature characteristics.

In the present embodiment, a wire member is wound around the outside of the magnetic core part 61b made of ferrite or the like and around the outside of the circumferential wall part 61c to form the excitation coils 860 and 862, and so it is possible to increase density of eddy current flowing into a measurement target. The detection coils 864 and 866 are also formed on the outside of the magnetic core part 61b and the outside of the circumferential wall part 61c, and so it is possible to efficiently collect the reverse magnetic field (interlinkage flux) generated.

As described above, the detection coils 864 and 866, and the dummy coils 868 and 870 constitute an anti-phase series circuit, both ends of which are connected to the respective resistor bridge circuits (not shown) including variable resistors. The excitation coils 860 and 862 are connected to the AC signal source 52 and generate alternating magnetic flux to thereby form an eddy current on the metal film (or conductive film) mf disposed in the vicinity. By adjusting a resistance value of the variable resistor, it is possible to ensure that the output voltage of the series circuit composed of the detection coils 864 and 866, and the dummy coils 868 and 870 becomes zero when there is no metal film (or no conductive film). In the present embodiment, total three resistor bridge circuits (not shown) including the one for the first sensor 500 in FIG. 3 are provided. Note that although a resistor bridge circuit is used in the present embodiment, the resistor bridge circuit is not necessarily required.

With the detection coil 864 and the dummy coil 868 connected to the bridge circuit, the output of the bridge circuit obtained can be used as the second signal 92. Alternatively the detection coil 866 and the dummy coil 870 are connected to the bridge circuit and the output of the bridge circuit obtained can be used as the second signal 92. Or, the sum of these two outputs can be used as the second signal 92.

The polishing apparatus 80 is equipped with a plurality of sensors (the first sensor 500 and the second sensor 502). The first sensor 500 and the second sensor 502 constitute a double monitoring system of varying film thicknesses to be measured. Thus, polishing performance is improved in the following two points.
(1) Preventing partial thin film remnants (residues)
(2) Improvement of polishing profile

(1) Preventing partial thin film remnants (residues) means the ability to remove small thin film remnants (residues). Preventing partial thin film remnants is made possible since the second sensor 502 more sensitive than the first sensor 500 is used together with the first sensor. Conventionally, the film thickness is monitored using a single sensor from the start of polishing when the metal film is spread over the entire surface of a wafer until the time the metal film across the entire surface is removed completely (this condition is called “cleared”). To make such monitoring possible, the measurement range of one sensor is adjusted to be wider. When the range is widened, polishing of the metal film advances, and when the metal film becomes thinner, the output of the sensor decreases. That is, the sensitivity (resolution in the vertical direction) with respect to the film thickness decreases. Therefore, the situation may be that the metal film has been completely removed or wafer monitoring after clearing the metal film has been difficult. Since the second sensor 502 more sensitive than the first sensor 500 is used in combination in the present embodiment, it is possible to detect small thin film remnants (residues). Therefore, small thin film remnants (residues) can be removed in the subsequent polishing steps.

Here, “more sensitive than” means to have higher sensitivity so that (1) it is possible to detect a smaller object (such as a smaller metal or semiconductor), and/or (2) in the case of an eddy current sensor, a stronger magnetic field can be generated, and/or (3) it is possible to detect a thinner metal film and/or (4) in the optical film thickness sensor, the beam spot diameter is finer and/or (5) in the case of an eddy current sensor, a stronger magnetic field is generated in a wider area.

In the case of an eddy current sensor, the number of windings of the coil needs to be increased or the outer diameter of the sensor needs to be increased to generate a stronger magnetic field. However, when the outer diameter of a sensor is increased, the film thickness measured value at an end part of the semiconductor wafer WH becomes more inaccurate. For this reason, it has been conventionally required to decrease the outer diameter of the eddy current sensor. When the outer diameter of the eddy current sensor is decreased, the magnetic field becomes weaker, making it impossible to detect thin film thickness. Moreover, when the outer diameter of the eddy current sensor is decreased, the area of a region through which the sensor passes within the semiconductor wafer WH surface (called the “monitoring area”) decreases. It is because the sensor passes through only a specific part within the wafer, part through which the sensor does not pass increases. Therefore, the problem is that there is a possibility that partial thin film remnants (residues) may have occurred in the part through which the sensor does not pass, and even when the sensor detects a polishing end, such thin film remnants (residues) may not have been detected.

In the present embodiment, the above-described problems have been solved by providing the first sensor 500 that outputs the first signal 90 (see FIG. 1) corresponding to film thickness of the film formed on the substrate, the second sensor 502 that is more sensitive than the first sensor and that outputs the second signal 92 (see FIG. 1) corresponding to the film thickness and the film thickness detector 88 (see FIG. 1) that detects film thickness of the film according to the second signal 92 when the film falls below a predetermined film thickness. That is, until the film thickness becomes thinner, it is possible to measure the film thickness including the edge part using mainly the first sensor 500. When the film thickness becomes thinner, the film thickness can be measured by using mainly the high sensitivity second sensor 502. Although the second sensor 502 is larger in size than the first sensor 500, since the second sensor 502 can generate a strong magnetic field, the detection coil of the second sensor 502 can detect and react a small metal without overlooking the small metal. As a result, since smaller thin film remnants (residues) can be removed through the subsequent polishing steps, the polishing profile improves. Here, the “polishing profile” means flatness quality of the polishing surface covering the entire semiconductor wafer WH. The flatter the entire polishing surface is, the better the polishing profile is.

When the film thickness detected by the first signal 90 falls below a predetermined film thickness, the end point detection controller 246 (film thickness detector) detects film thickness of the film by using the second signal 92 as will be described later. The first sensor 500 and the second sensor 502 are eddy current sensors in the present embodiment. When the film falls below the predetermined film thickness, the second signal 92 outputted from the second sensor 502 is at a saturation level or below.

Here, that the signal is at a saturation level or below means the following: That the second signal 92 is at the saturation level means that when the film thickness detected by the second sensor 502 exceeds a certain thickness, the scale of the second signal 92 cannot keep up with the increase in film thickness. In other words, when the film thickness exceeds a certain scale, the second signal 92 takes a substantially fixed value. That the signal is at the saturation level or below means that the film thickness detected by the second sensor 502 is thinner than a certain thickness and the second signal 92 changes according to the film thickness. Since the second sensor 502 has higher sensitivity than that of the first sensor 500, the first sensor 500 reaches the saturation level with the film thickness thinner than the film thickness when the first signal outputted from the first sensor 500 reaches the saturation level.

As has been already described, the first sensor 500 is an eddy current sensor and the first sensor 500 is smaller in size than the second sensor 502. For example, when the external dimensions (W2 in FIG. 3) of the first sensor 500 are 1 cm or less, L1 in FIG. 4 of the second sensor 502 has a scale on the order of 2 cm. The magnetic field generated in the film by the second sensor 502 is stronger than the magnetic field generated in the film by the first sensor 500.

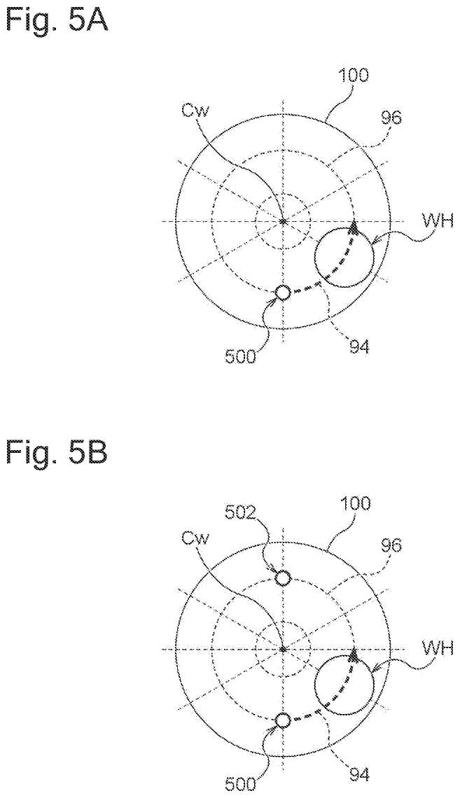

FIG. 5 illustrates a conventional sensor arrangement and that of the present embodiment. FIG. 5A illustrates a conventional sensor arrangement. FIG. 5B illustrates a sensor arrangement of the present embodiment. In the conventional sensor arrangement shown in FIG. 5A, one first sensor 500 is arranged on the polishing table 100. The first sensor 500 passes through the center of the semiconductor wafer WH in a path as a trace 94 as the polishing table 100 rotates.

According to the sensor arrangement of the present embodiment shown in FIG. 5B, the first sensor 500 and the second sensor 502 are arranged on the polishing table 100. The first sensor 500 passes through the center of the semiconductor wafer WH as the trace 94 as the polishing table 100 rotates. The second sensor 502 is arranged at a position symmetric to the first sensor 500 with respect to the center of rotation Cw of the polishing table 100 in the present embodiment. In other words, the first sensor 500 and the second sensor 502 are arranged on a circle 96 and the trace thereof is the circle 96. The second sensor 502 also passes through the center of the semiconductor wafer WH as the polishing table 100 rotates.

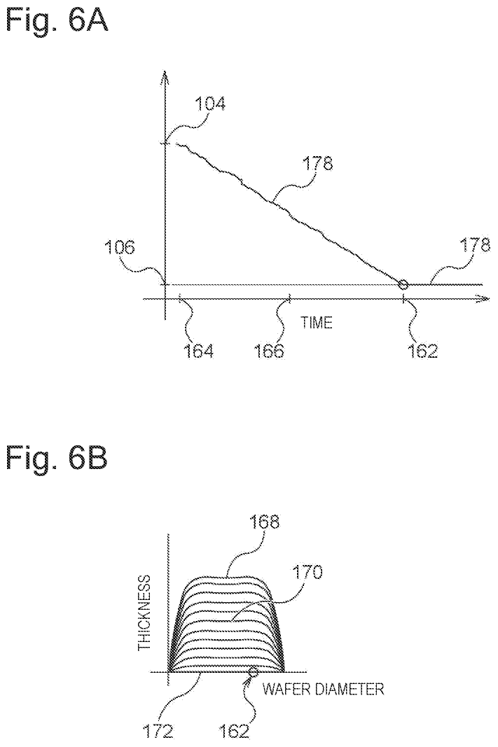

FIG. 6 illustrates conventional film thickness measurement results by the first sensor 500 in FIG. 5A. FIG. 6A shows a film thickness time variation at specific positions on the semiconductor wafer WH (e.g., center of the semiconductor wafer WH). The horizontal axis shows elapsed time for polishing (unit: sec) and the vertical axis shows film thickness (unit nanometer: nm). Conventionally, the film thickness of the film from the condition of thick film (polishing start, film thickness 104 of the film) to a thin film (film thickness of the film is a predetermined film thickness 106) is detected by only the first signal. At time 162, when the predetermined film thickness 106 is detected, it is determined that all the films to be removed have been removed. At time 162, the polishing is stopped.

FIG. 6B illustrates film thickness distribution across the semiconductor wafer WH. The horizontal axis represents a position (unit representing millimeter: mm) of a certain one diameter direction of the semiconductor wafer WH and the vertical axis illustrates film thickness (unit representing nanometer: nm). The scale of the diameter (wafer diameter) is, for example, 300 mm. Each of 12 lines shown as an example in the drawing indicates film thickness distribution at fixed time intervals from the polishing start time to the polishing end time. A wire 168 illustrates film thickness distribution at the polishing start time (time 164), a wire 172 illustrates film thickness distribution at the polishing end time (time 162), a wire 170 illustrates film thickness distribution at an intermediate point in time (time 166) of polishing. At the polishing end time (time 162), residues cannot be monitored due to the lack of resolution of the thin film of the first sensor 500 and partial thin film remnants (residues) may be generated.

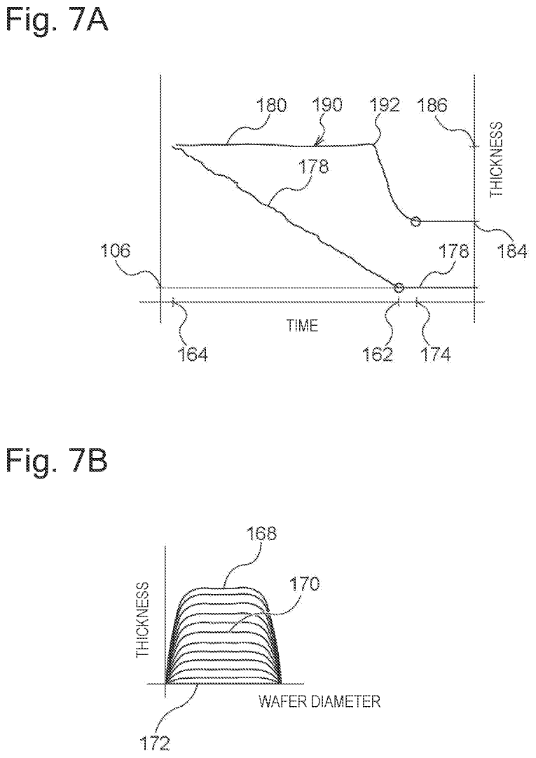

In the present embodiment, the film thickness detector 88 detects the film thickness of the film by using the first signal and the second signal from a thick film condition (polishing start, film thickness 104 of the film) to thin film (film thickness of the film is the predetermined film thickness 106). When the film thickness of the film falls below a predetermined film thickness 106, the film thickness detector 88 detects the film thickness of the film by using the second signal. Therefore, it is possible to detect the film thickness of the film up to film thickness 184 (see FIG. 7A) thinner than the predetermined film thickness 106. As a result, it is possible to polish thin film remnants (residues) in the subsequent polishing steps and prevent partial thin film remnants (residues). Note that in the present embodiment, although the predetermined film thickness 106 is film thickness, which is a detection limit by the first sensor 500, the predetermined film thickness is not limited to this. The predetermined film thickness is equal to or more than the film thickness, which is the detection limit by the first sensor 500, and may be (film thickness within the measurement range of second sensor 502) of the film thickness within which the second sensor 502 can detect the film thickness.

FIG. 7 is a diagram illustrating film thickness measurement results by the first sensor 500 and the second sensor 502 in FIG. 5B. FIG. 7A illustrates a time variation in film thickness in at specific positions (for example, the center of the semiconductor wafer WH) within the semiconductor wafer WH. The horizontal axis represents elapsed time for polishing (unit representing second: sec) and the vertical axis represents film thickness (unit representing nanometer: nm). A graph 178 represents film thickness according to the first sensor 500. The graph 178 is the same as the graph 178 shown in FIG. 6. The graph, that is, a film thickness value is, for example, time-related moving average and time-related moving average is, for example, an average value of three measured values that are consecutive in time.

A graph 180 illustrates film thickness detection results by the second sensor 502. Since the graph 180 shows a smaller change than the graph 178, a change between the minimum film thickness 184 detected by the second sensor 502 and the film thickness 186 at the polishing start is shown enlarged from the graph 178. That is, the scale on the vertical axis on the right side and the scale on the vertical axis on the left side in FIG. 7A are different. The graph 178 is represented by the left vertical axis and this is the same as the vertical axis in FIG. 6A. The graph 180 is represented by the right vertical axis. At time 174, the film thickness corresponds to film thickness 184 thinner than the film thickness 106. At the time 174, when the film thickness 184 thinner than the film thickness 106 is detected, all the films to be removed are determined to have been removed. The polishing is stopped at time 174. The film thickness 186 by the second sensor 502 at the polishing start time is in a saturation condition and the graph 180 starts to decline at the point in time when polishing has advanced to some extent.

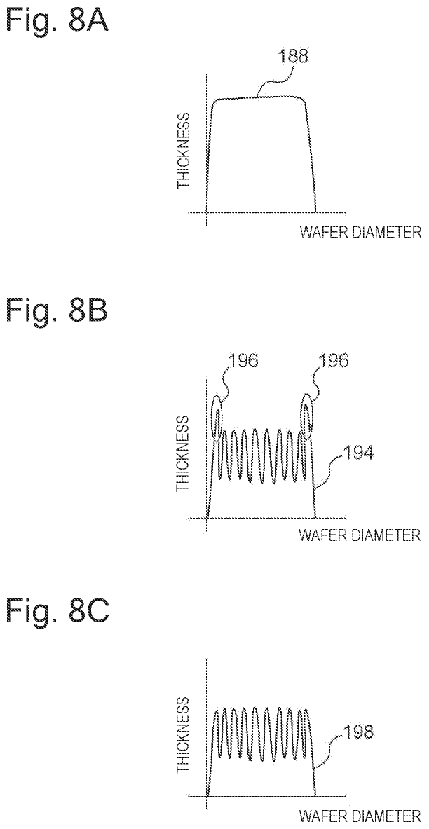

FIG. 7B is identical to FIG. 6B. In FIG. 7B, since the film thickness is minute, film thickness distribution after the time 162 cannot be displayed. Therefore, FIG. 8 shows a film thickness distribution measured by the second sensor 502 showing an enlarged view from the time 162 onward. Respective drawings in FIG. 8 illustrate film thickness distribution across the semiconductor wafer WH. The horizontal axis represents a position (unit representing millimeter: mm) in a certain one diameter direction of the semiconductor wafer WH and the vertical axis represents film thickness (unit representing nanometer: nm). The scale of the diameter (wafer diameter) is, for example, 300 mm. The reasons that there are many peak waveforms in the graph in FIG. 8 are as follows. Since the second sensor 502 has high sensitivity, the second sensor 502 reacts differently for the area in the semiconductor wafer WH surface where metal exists (wiring area) and for the area where no metal exists (insulator part). In the area where the metal exists, the output increases (film thickness is thick), whereas the area where the film thickness is thin, no metal exists, the output decreases (film thickness is thin). As a result, many peak waveforms appear in the graph in FIG. 8. The time at which the film thickness detector 88 determines that there is no more residue 196 at an end part (peak part) corresponds to the polishing end time 174.

The reason that while there are many peaks in the graph in FIG. 8, many peaks do not appear in the graph 180 in FIG. 7A is that the peak top (peripheral to the wiring part) and the valley (peripheral to the insulator part) always appear at the same locations. When attention is focused on a time variation of a specific part (for example, central part) within the semiconductor wafer WH, the part corresponds to, for example, a peak top or a valley part or an intermediate part thereof, and so many peaks do not appear.

A graph 188 shown in FIG. 8A illustrates a film thickness distribution at the time a measured value 190 in the graph 180 was measured. The film thickness by the second sensor 502 starts to decline from the time at which a measured value 192 of the graph 180 was measured. A graph 194 shown in FIG. 8B illustrates a film thickness distribution immediately before the time 174 when time 162 elapses. It can be seen that there is residue 196 at an end part of the semiconductor wafer WH. A graph 198 shown in FIG. 8C illustrates a film thickness distribution at the time 174. It is known that the residue 196 has been removed at the end part of the semiconductor wafer WH. A uniform film thickness is achieved across the semiconductor wafer WH.

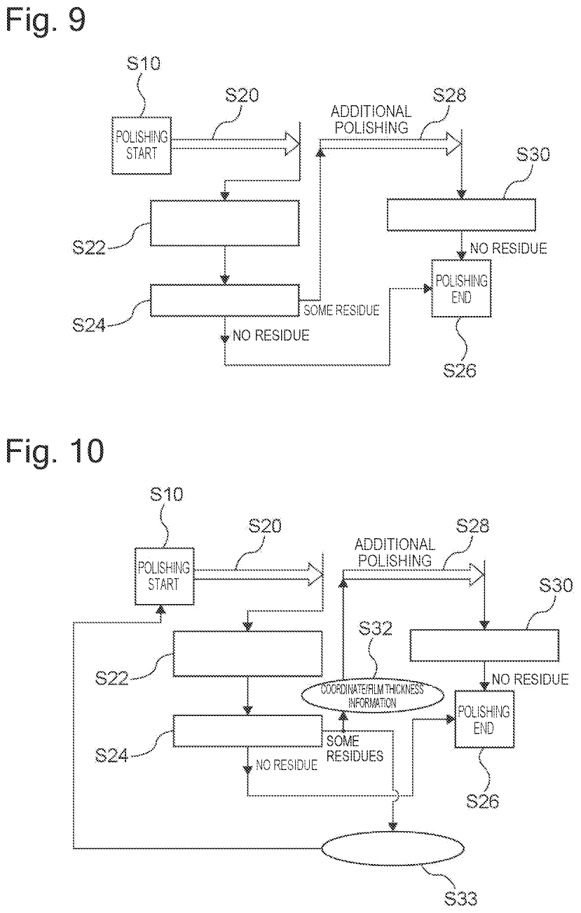

FIG. 9 illustrates a flowchart of a polishing process in the present embodiment. When the device control controller 248 starts the polishing process (step S10), polishing is performed until the time 162 at which the end point detection controller 246 (film thickness detector 88) detects a polishing end by using the first sensor 500 (step S20). When the time 162 comes, and if the end point detection controller 246 detects a polishing end by using the first sensor 500 (step S22), the device control controller 248 starts polishing by using the second sensor 502. The film thickness detector 88 determines, from the output of the second sensor 502, whether there is no more residue 196 (step S24). When the film thickness detector 88 determines that there is no more residue 196, the polishing ends (step S26).

When the film thickness detector 88 determines that there is residue 196, additional polishing is performed (step S28). Then, the film thickness detector 88 determines, from the output of the second sensor 502, whether there is no more residue 196 (step S30). When the film thickness detector 88 determines that there is no more residue 196, the device control controller 248 ends the polishing (step S26). A more specific thickness of the film thickness 106 is determined by polishing conditions. For example, there may be a case where 0 nm is set or a case where a value larger than 0 nm may be set. The polishing conditions may include thickness of wire to be left after polishing. There are various thicknesses of wires that should be left after polishing.

Next, a flowchart when coordinates of residues (positions of residues within the semiconductor wafer WH) and film thickness information are used in the next step or the next wafer after the polishing process will be described with reference to FIG. 10. The reason that coordinates of residues and film thickness information of the residues are used in the next step or the next wafer is that when there are locations where residues are generated in advance or locations where residues are likely to be generated, it is possible to increase the pressure of the part from the polishing start and process the residues in early stages. This makes it possible to shorten polishing time and improve polishing accuracy. The flow shown in FIG. 10 corresponds to additional processing added to the flow shown in FIG. 9. Only the additional flow will be described. When determining whether there is no more residue 196 from the output of the second sensor 502 (step S24), and if there are residues, the film thickness detector 88 accumulates coordinates of the residues and film thickness information of the residues in memory (step S32). After that, the film thickness detector 88 performs additional polishing (step S28). Note that when the film thickness detector 88 determines from the output of the second sensor 50 whether there are residues 196 (step S24), if there are residues, the film thickness detector 88 accumulates coordinates of the residues and film thickness information of the residues in memory (step S33), and can polish the next wafer based on this information (step S10 for the next wafer).

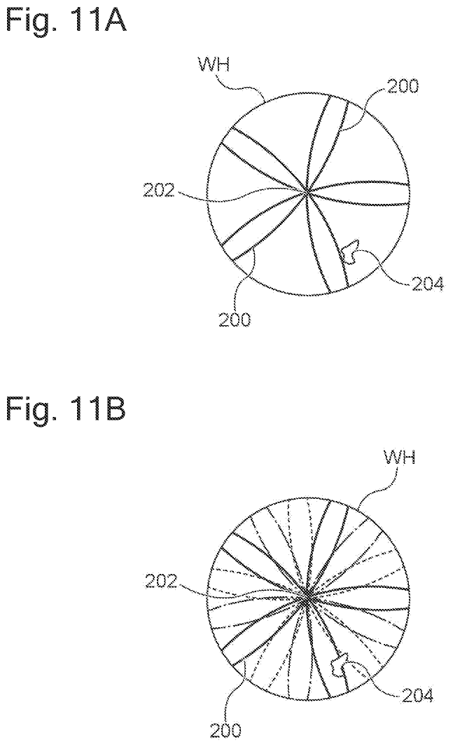

In the present embodiment, there are more sensors than before. The resulting effects will be described with reference to FIG. 11. FIG. 11A shows traces 200 of the first sensor 500 within the semiconductor wafer WH when only the conventional first sensors 500 are used. In the case of the present drawing, 10 traces 200 extend from a center 202 of the semiconductor wafer WH. The number of the traces 200 is determined by the number of revolutions of the polishing table 100, the number of revolutions of the top ring 146 and the number of sensors. The greater the number of sensors, the greater the number of traces 200.

FIG. 11B illustrates traces 200 of the first sensor 500 within the semiconductor wafer WH when there are three sensors (e.g., when there are one first sensor 500 and two second sensors 502). In the case of the present drawing, 30 traces 200 extend from the center 202 of the semiconductor wafer WH. The more sensors, that is, the greater the number of traces 200, the greater area within the semiconductor wafer WH can be measured, and so the measuring accuracy increases consequently. Moreover, it is less likely to overlook residues 204. Therefore the measurement accuracy increases and the polishing accuracy increases as a consequence.

In the present embodiment, the first sensor 500 is smaller in size than the second sensor 502. That is, the second sensor 502 is larger in size than the first sensor 500. The effect of a larger sensor diameter will be described with reference to FIG. 11. When only the first sensor 500 which is conventionally smaller in FIG. 11A is used, there is a high probability of overlooking the small residue 204. On the other hand, in the present embodiment, the second sensor 502 is greater in size than the first sensor 500, and so even when the second sensor 502 passes through the same trace 200 as the trace 200 shown in FIG. 11A, the detection range of the second sensor 502 becomes wider. That is, with the sensor with greater diameter, the area through which the sensors pass increases. Thus, with the greater sensor diameter, the monitoring area within the wafer surface can be widened. Therefore, the measuring accuracy increases and the polishing accuracy increases consequently.

Next, as another embodiment, using the sensor in FIG. 5B for pressure control will be described. The top ring 146 (see FIG. 1) is provided with an airbag 206 to press the semiconductor wafer WH, and the airbag 206 is divided into, for example, four compartments. The airbag 206 is provided in the top ring 146, for example. In addition to or instead of it, the airbag 206 may also be provided in the polishing table 100. The airbag 206 is a member to adjust the polishing pressure of the semiconductor wafer WH for each area of the semiconductor wafer WH. The airbag 206 is configured to change its volume due to a pressure of air introduced thereinto. Note that although the name is the “air” bag, a fluid other than air, for example, nitrogen gas or pure water may be introduced into the airbag 206.

The four airbags 206 are connected to their respective pressure control valves (not shown). The pressure control valves are connected to the device control controller 248 to individually adjust the respective pressures of the pressure fluids (e.g., gas) to be supplied into the four compartments according to the control signal 208 (see FIG. 1) from the device control controller 248. This allows a pressure in each of the four compartments to be adjusted. The device control controller 248 detects locations where residues exist from the output of the second sensor 502 and increases the pressure of the airbag 206 corresponding to the locations where residues exist.

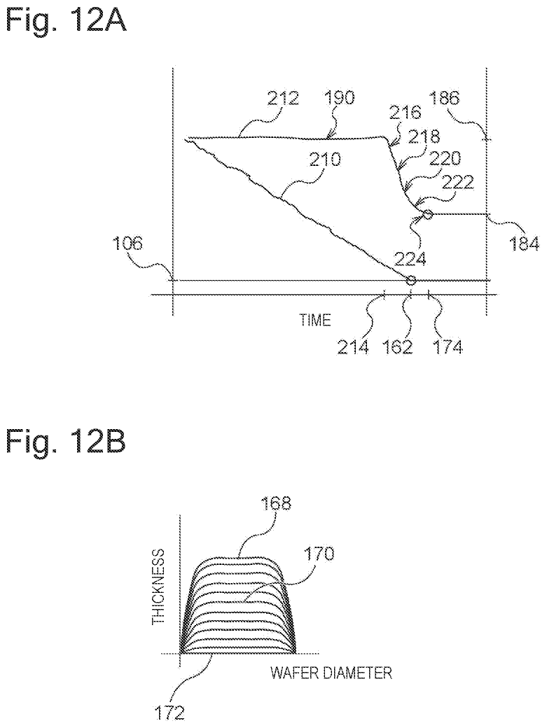

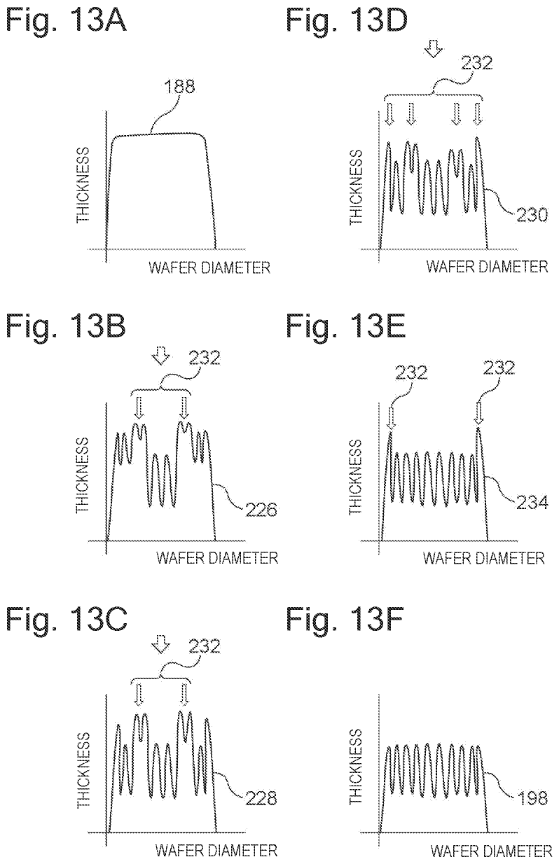

The method of detecting locations where residues exist will be described with reference to FIGS. 12 and 13. FIG. 12 illustrates film thickness measurement results by the first sensor 500 and the second sensor 502 in FIG. 5B. FIG. 12A illustrates a time variation in film thickness at specific positions (e.g., center of the semiconductor wafer WH) within the semiconductor wafer WH. The horizontal axis and the vertical axis in FIG. 12 are the same as those in FIG. 7. A graph 210 illustrates film thickness according to the first sensor 500. The graph 210 is substantially identical to the graph 178 shown in FIG. 6.

A graph 212 illustrates film thickness detection results by the second sensor 502. The graph 212 has a smaller change than the graph 210, and so a change between the minimum film thickness 184 detected by the second sensor 502 and the film thickness 186 at the polishing start is illustrated, enlarged from the graph 210. In other words, the vertical axis on the right and the vertical axis on the left in FIG. 12A are different in scales. The graph 210 is represented by the vertical axis on the left side and this is the same as the vertical axis in FIG. 6A. The graph 212 is represented by the vertical axis on the right side. At the time 174, which is the polishing end time, the film thickness becomes a film thickness 184 thinner than the film thickness 106 (or although the film thickness is the same, there is no more residue). At the time 174, when the film thickness 184 thinner than the film thickness 106 is detected (or although the film thickness is the same, there is no more residue) it is determined that all the films to be removed have been removed. At the time 174, polishing is stopped. The film thickness 186 according to the second sensor 502 at the polishing start is in a saturation condition and the graph 212 starts to decline at the time 214 at which the polishing has advanced to some extent.

FIG. 12B is a graph corresponding to FIG. 6B. In FIG. 12B, since the film thickness is minute, a detailed film thickness distribution after time 214 cannot be displayed. For this reason, an enlarged view of the film thickness distribution measured by the second sensor 502 after the time 214 is shown in FIG. 13. Each drawing in FIG. 13 illustrates a film thickness distribution across the semiconductor wafer WH. The horizontal axis represents a position in a certain one diameter direction of the semiconductor wafer WH (unit representing millimeter: mm) and the horizontal axis represents a position in the one diameter direction (unit representing nanometer: nm) and the vertical axis represents film thickness. The scale of the diameter (wafer diameter) is, for example, 300 mm.

The graph 188 shown in FIG. 13A illustrates a film thickness distribution at the time at which the measured value 192 (see FIG. 7A) of the graph 212 was measured. The film thickness by the second sensor 502 starts to decline from the time 214 after the time at which the measured value 192 of the graph 212 was measured. A graph 226 shown in FIG. 13B illustrates a film thickness distribution at the time 216 after which the time 214 elapses. It is seen that there is a residue 232 at an end part of the semiconductor wafer WH. The graphs 228, 230 and 232 shown in FIG. 13C, FIG. 13D and FIG. 13E illustrate film thickness distributions at the time at which the measured values 218, 220 and 222 of the graph 212 were measured. It is seen that the semiconductor wafer WH has a residue 232.

The graph 198 shown in FIG. 13F illustrates a film thickness distribution at the time 174. It is seen from the drawing that the residue 232 has been removed at the end part of the semiconductor wafer WH. A uniform film thickness has been achieved across the semiconductor wafer WH.

There are various methods of detecting the presence of residues as follows. At least one or a combination of a plurality of the following methods can be used.

(1) The averages of the peak value are found in the respective drawings of FIG. 13 and it is determined that a residue can be found at the location of the second largest peak value above the average.
(2) In the respective drawings of FIG. 13, the location of a maximum peak value is determined to be the location of a residue.
(3) In the respective drawings of FIG. 13, the location of a peak value which exceeds the average by a predetermined value or more is determined to be the location of a residue.
(4) The location of a peak value larger than the predetermined value is determined to be the location of a residue.
(5) Since it is often the case that no residue is found in the center of the semiconductor wafer WH, the location of a peak value larger than the peak value in the center in the respective drawings of FIG. 13 by the predetermined value is determined to be the location of a residue. Note that the above peak value may also be the average of a film thickness value for each part of the semiconductor wafer WH

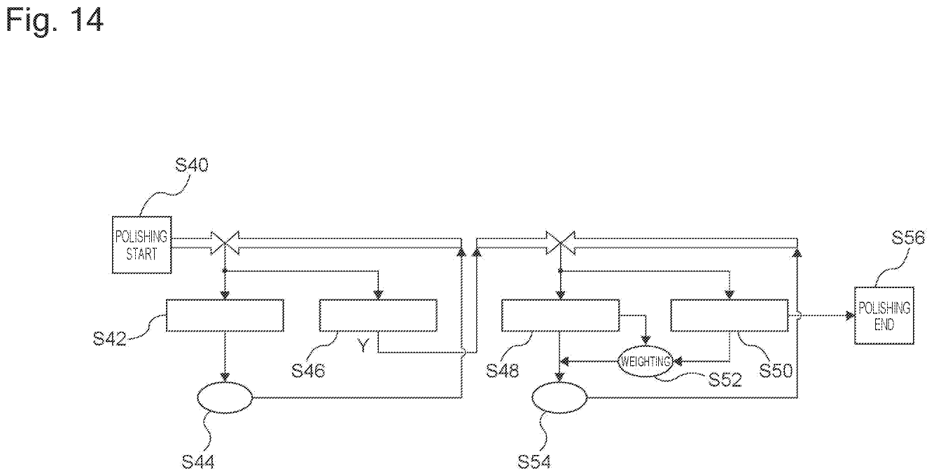

FIG. 14 shows a flowchart of a polishing process in the present embodiment. The process differs after the time 214 shown in FIG. 12A. The time 214 is the time at which the graph 212 starts to decline. From the time 214 onward, the output signal of the second sensor 502 is used for pressure control.

When the polishing process starts (step S40), the device control controller 248 causes the polishing process to start. The film thickness detector 88 performs film thickness monitoring by using the first sensor 500 (step S42). The film thickness detector 88 sends the film thickness distribution obtained to the device control controller 248 (step S42). The device control controller 248 performs control of the airbag 206 based on the film thickness distribution obtained (step S44). The film thickness detector 88 also performs film thickness monitoring by using the second sensor 502 simultaneously (step S46). The film thickness detector 88 is monitoring whether the film thickness according to the second sensor 502 starts to decline or not (step S46).

Once the film thickness detector 88 confirms that the film thickness according to the second sensor 502 starts to decline at the time at which a measured value 192 of the graph 212 (see FIG. 7A) is measured (step S46), the film thickness detector 88 proceeds to step S48. In step S48, the film thickness detector 88 performs film thickness monitoring according to the first sensor 500. The film thickness detector 88 also performs film thickness monitoring by the second sensor 502 simultaneously (step S50). The film thickness detector 88 weights the film thicknesses obtained by the first sensor 500 and the second sensor 502 (step S52). As for the weighting, for example, from the time 214 to the time 162, the weight of the film thickness obtained by the second sensor 502 is increased from 0 to 1 and the weight of the film thickness obtained by the first sensor 500 is decreased from 1 to 0. From the time 162 onward, the film thickness weight obtained by the second sensor 502 is assumed to be 1 and the film thickness weight obtained by the first sensor 500 is assumed to be 0.

The film thickness detector 88 sends the film thickness distribution obtained to the device control controller 248 (step S48). The device control controller 248 performs control of the airbag 206 based on the film thickness distribution obtained (step S54). The film thickness detector 88 is also monitoring end point detection of polishing according to the second sensor 502 (step S50). When the time 162 comes, if the end point detection controller 246 detects a polishing end according to the first sensor 500 (step S48), the device control controller 248 continues polishing by using only the second sensor 502. The film thickness detector 88 determines whether there is no more residue 196 from the output of the second sensor 502 (step S50). When the film thickness detector 88 determines that there is no more residue 196, the device control controller 248 terminates the polishing (step S56).

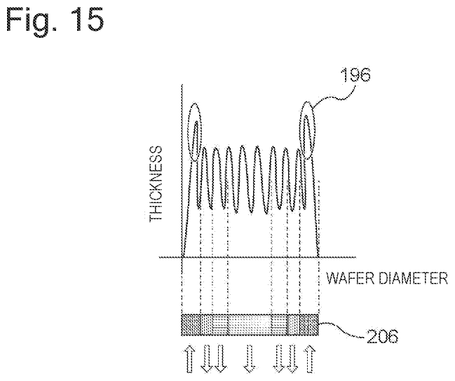

Note that FIG. 15 shows a control example of the airbag 206 in the case where there is residue 196 as shown in FIG. 13E. The airbag 206 in the present drawing is divided into four compartments from the center of the semiconductor wafer WH toward the end part. Note that the number of partitions of the airbag 206 is not limited to this. FIG. 15 also shows FIG. 13E together. In the control of the airbag 206, the pressure of the airbag 206 at the position corresponding to the residue 196 is increased or decreased in accordance with the condition of the residue 196. In the case of FIG. 15 (that is, in the case of FIG. 13E), since the residue 196 is located at an end part of the semiconductor wafer WH, the pressure of the airbag 206 located at the end part is caused to increase and the pressure of the airbag 206 located at any location other than the end part is caused to decrease. An upward arrow shown in the drawing means an increase of pressure of the airbag 206, whereas a downward arrow means a decrease of pressure of the airbag 206.

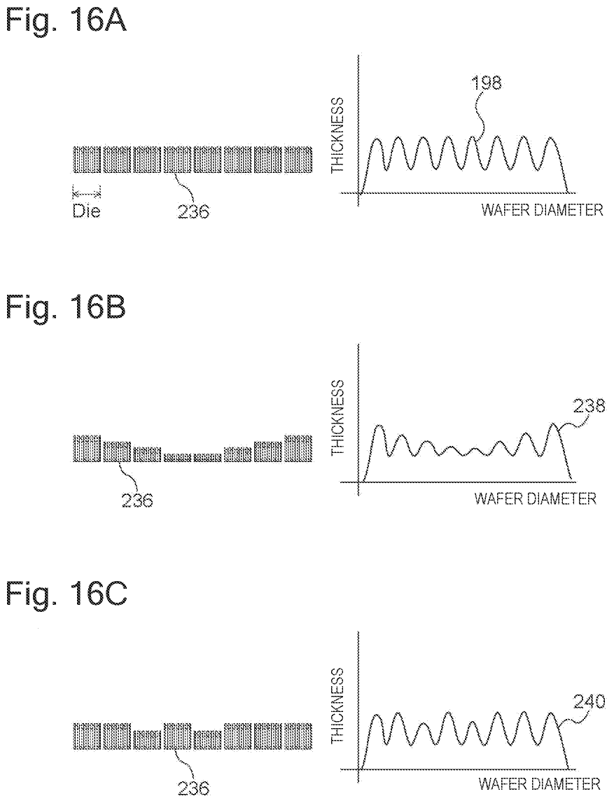

Next, monitoring of polishing abnormality by the second sensor 502 will be described with reference to FIG. 16. There are a variety of polishing abnormality. Monitoring of erosion, which is a kind of polishing abnormality will be described. “Erosion” refers to a phenomenon that an insulating film at a certain location is excessively shaved down to the peripheral insulating film surface or below, together with a wiring pattern (copper (Cu) or the like) at the certain location. FIG. 16A illustrates normal polishing results. FIG. 16B and FIG. 16C show that erosion has occurred. Eight dies 236 (semiconductor chips) are displayed on the left side of FIG. 16A, FIG. 16B and FIG. 16C. The graph 198 corresponding to FIG. 8C is displayed on the right side of FIG. 16A, FIG. 16B and FIG. 16C.

A comparison of the graph 238 in FIG. 16B and the graph 198 in FIG. 16A shows that erosion has occurred, the neighborhood of the center of the semiconductor wafer WH corresponding to the bottom of the erosion in FIG. 16B. A comparison of the graph 240 in FIG. 16C and the graph 198 in FIG. 16A shows that erosion has occurred non-uniformly on the semiconductor wafer WH in FIG. 16C.

The device control controller 248 calculates film thickness from the output of the second sensor 502 and determines the location of the erosion from position coordinates within the semiconductor wafer WH and the film thickness at the part corresponding to the position coordinates. The device control controller 248 performs polishing to correct the erosion. Alternatively, the device control controller 248 determines that the degree of erosion is small, and continues or terminates the polishing.

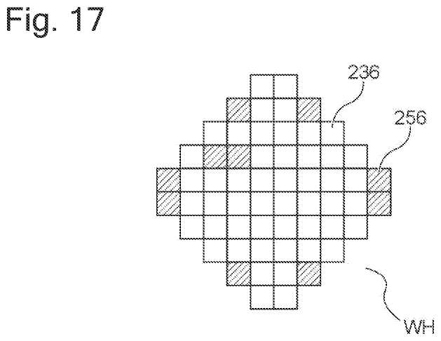

The device control controller 248 may display the polishing results on a monitor as shown in FIG. 17. FIG. 17 is an example of the film thickness measurement results by the second sensor 502 of one semiconductor wafer WH after the polishing end displayed on the monitor. In the present drawing, the circular semiconductor wafer WH is divided into 10 compartments in the diameter direction and displayed. A shaded compartment 250 represents an area with the highest film thickness based on the area with the thinnest film thickness. There can be various kinds of methods for displaying film thickness distribution. The semiconductor wafer WH may be divided into, for example, 20 compartments in the diameter direction and displayed. Furthermore, the film thickness distribution can be displayed in colors and with 256 gradations and the like.

In the respective embodiments of the present invention described so far, two sensors with different sensitivities (the first sensor 500 and the second sensor 502) are operated simultaneously. The second sensor 502, which is at least a high sensitivity sensor measures film thickness at the end point detection time (time 162) of the first sensor 500, the low sensitivity sensor. Although it is different from the embodiment of the present invention, there is also a method (hereinafter called “comparative example”) of detecting an end point by using one sensor (first sensor 500) and then changing the sensor to another sensor (high sensitivity sensor).

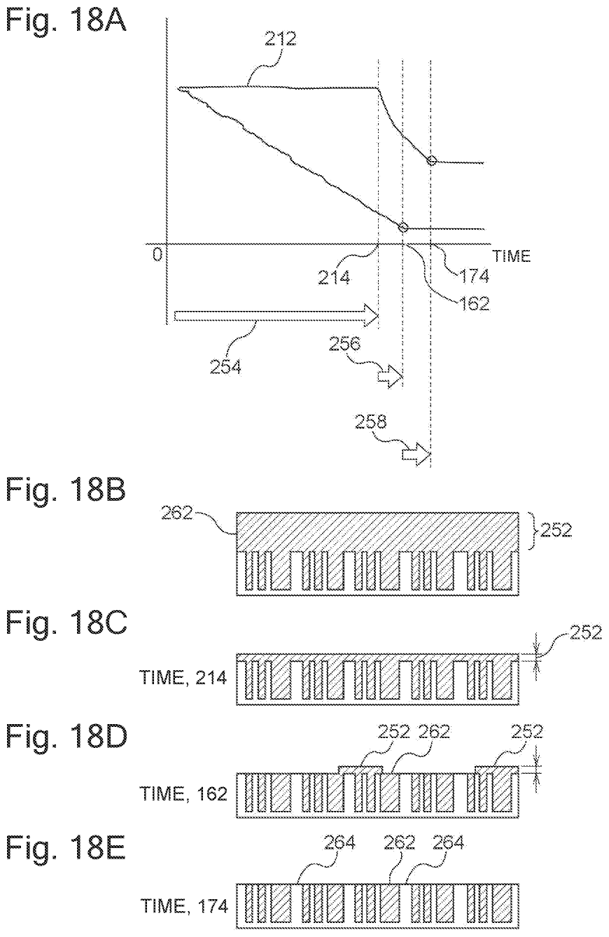

Differences between the embodiment of the present invention shown in FIG. 7 and the comparative example will be described with reference to FIG. 18. FIG. 18 illustrates an embodiment of the present invention. FIG. 18A is substantially identical to FIG. 7, and is a drawing highlighting main parts. As shown in FIG. 18A, in a period 254 from a polishing start to time 214, at least the first sensor 500 is operated and film thickness is measured by using only the first sensor 500. From the time 214 to the time 162, the first sensor 500 and the second sensor 502 are simultaneously operated, and film thickness is measured by the first sensor 500 and the second sensor 502. From the time 162 to the time 174, at least the second sensor 502 is operated, and film thickness is measured by only the second sensor 502. Next, polishing conditions corresponding to these time periods are shown in FIG. 18B to FIG. 18E. FIG. 18B to FIG. 18E are cross-sectional views illustrating polishing conditions of the semiconductor wafer WH. FIG. 18B illustrates the conditions of the film 252 to be polished at the polishing start. FIG. 18C, FIG. 18D and FIG. 18E illustrate conditions of the film 252 to be polished at the time 214, 162 and 174 respectively. In FIG. 18C, the film 252 still remains as a thin and uniform film. In FIG. 18D, the film 252 remains at two locations. In FIG. 18E, no more film 252 remains. In these drawings, the metal 262 that constitutes the film 252 is removed and the remaining metal 262 in FIG. 18E is wiring. The metal 262 in FIG. 18E is separated by an insulator 264.

Most of the film 252 (metal) within the surface of the semiconductor wafer WH has been removed in the condition in FIG. 18D. As shown in the comparative example, even if the sensor is changed to a high sensitivity sensor from the stage in FIG. 18D and the high sensitivity sensor is used for pressure control during polishing, almost no film 252 (metal) remains, the polishing advances during the change from the condition, and more residues are gone, and so there is almost no effect of switching. According to the embodiment of the present invention, information that the second sensor 502 (has high resolution for thin film) can also be used for pressure control during polishing from the stage in FIG. 18C. For this reason, compared to the comparative example, it is possible to polish the metal surface more uniformly, unlikely to reach the condition in FIG. 18D.

According to the embodiment of the present invention, pressure control is continued from the stage in FIG. 18D for the metal residue remaining even in the stage in FIG. 18D using the second sensor 502, and it is thereby possible to clearly polish the entire surface while preventing excessive polishing of a pattern surface.

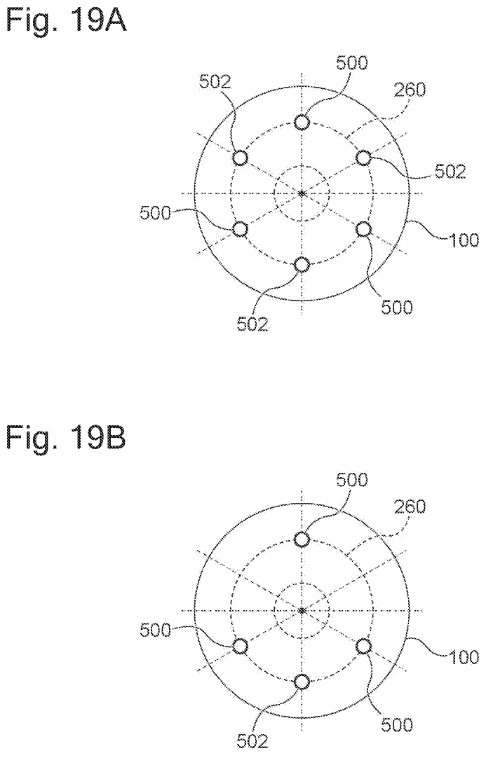

Next, the polishing apparatus according to the embodiment of the present invention includes a plurality of first sensors 500 and/or can include a plurality of second sensors 502. This will be described with reference to FIG. 19. FIG. 19 illustrates an arrangement of sensors inside the polishing table 100 when at least one of the first sensor 500 and the second sensor 502 is provided in plurality. The first sensor 500 and the second sensor 502 are arranged on the circumference of substantially one circle 260 inside the polishing table 100.

As shown in FIG. 19A, there are a plurality of (3) first sensors 500, the first sensors 500 are arranged at mutually and substantially equal intervals on the circumference of the circle 260, and there are a plurality of (3) second sensors 502, and the second sensors 502 are arranged at mutually and substantially equal intervals on the circumference. The number of first sensors 500 is equal to the number of second sensors 502. The first sensors 500 and the second sensors 502 are arranged alternately on the circumference. In FIG. 19B, the number of first sensors 500 is different from the number of second sensors 502.

As shown in the present drawing, when the number of sensors is plural, accuracy of detecting film thickness values improves. When the number of sensors is plural, the monitoring area within the surface of the semiconductor wafer WH extends, and it is less likely to overlook residues. It is particularly preferable to arrange a plurality of second sensors 502 that are larger in size.

Next, according to FIG. 1, control of the entire polishing apparatus by the device control controller 248 will be described. The device control controller 248, the main controller, includes a CPU, a memory, a recording medium and software recorded in the recording medium or the like. The device control controller 248 performs monitoring and control of the entire polishing apparatus, and sends/receives signals, records and calculates information therefor. The end point detection controller 246 includes a CPU, a memory, a recording medium and software recorded in the recording medium or the like. The end point detection controller 246 incorporates a program that functions as an end point detection means for detecting a polishing end point indicating a polishing end. The device control controller 248 incorporates a program that functions as a control means for controlling polishing. The programs are updatable. Note that the programs may not be updatable. The device control controller 248 may also function as the end point detection controller 246.

Note that the end point detection controller 246 and the device control controller 248 execute the control means for controlling polishing, the film thickness detector and the end point detection means by software, but the control means, the film thickness detector and the end point detection means may also be executed by an electronic circuit.

The above embodiment has been described assuming that the first sensor 500 and the second sensor 502 are eddy current sensors. However, as the first sensor 500, it is possible to use a current sensor that detects currents of the top ring motor 114, the motor 176 and a swing motor for the top ring head shaft 117 to measure film thickness. An optical film thickness sensor may be used as the first sensor 500 and the second sensor 502.

Next, an example of the polishing method will be described. According to the polishing method, the top ring 146 presses the semiconductor wafer WH against the polishing pad 101 to polish the film provided for the semiconductor wafer WH. The first sensor 500 outputs a first signal corresponding to the film thickness of the film. The second sensor 502 more sensitive than the first sensor 500 outputs a second signal corresponding to the film thickness. The end point detection controller 246 (film thickness detector) detects the film thickness of the film by using the first signal and the second signal before the film reaches a predetermined film thickness. The end point detection controller 246 (film thickness detector) detects the film thickness of the film when the film thickness of the film falls below the predetermined film thickness using the second signal.

According to the polishing method, the polishing pad 101 to polish the semiconductor wafer WH or the film formed on the semiconductor wafer WH is affixed to the polishing table 100. The top ring 146 is provided with a plurality of pressure chambers 206. The device control controller 248 (controller) controls pressures within the plurality of pressure chambers 206 provided in the top ring 146 in accordance with the film thickness detected by the end point detection controller 246, the top ring 146 presses the semiconductor wafer WH against the polishing pad 101 in a condition in which the pressures within the plurality of pressure chambers 206 are controlled, and the film provided on the semiconductor wafer WH is thereby polished.

Examples of the embodiments of the present invention have been described so far, the above embodiments of the present invention are intended to facilitate an understanding of the present invention, but not intended to limit the present invention. The present invention can be changed or modified without departing from the spirit and scope of the present invention and it goes without saying that the present invention includes equivalents thereof. Any combinations or omissions of the components described in the scope of patent claims and the specification within the scope in which at least some of the above problems can be solved or the extent to which at least some of the effects can be achieved.

This application claims priority under the Paris Convention to Japanese Patent Application No. 2023-34763 filed on Mar. 7, 2023. The entire disclosure of Japanese Patent Laid-Open No. 2022-83705 including specification, claims, drawings and summary is incorporated herein by reference in its entirety.

### REFERENCE SIGNS LIST

WH . . . semiconductor wafer
50 . . . eddy current sensor
80 . . . polishing apparatus
88 . . . film thickness detector
100 . . . polishing table
101 . . . polishing pad
110 . . . top ring head
154 . . . eddy current sensor
196 . . . residue
206 . . . pressure chamber
246 . . . end point detection controller
248 . . . device control controller
500 . . . first sensor
502 . . . second sensor

What is claimed is:

1. A polishing apparatus comprising:
a polishing table with a polishing pad for polishing a film formed on a substrate;
a holder configured to hold the substrate and press the substrate against the polishing pad;
a first sensor that outputs a first signal corresponding to film thickness of the film;
a second sensor that is more sensitive than the first sensor and that outputs a second signal corresponding to film thickness of the film; and
a film thickness detector that detects, when the film thickness is equal to or smaller than a predetermined film thickness, the film thickness of the film according to the second signal and detects, when the film is thicker than the predetermined film thickness, the film thickness of the film according to the first signal and the second signal.

2. The polishing apparatus according to claim 1, wherein when the film thickness of the film detected by the first signal falls below the predetermined film thickness, the film thickness detector detects the film thickness of the film by using the second signal.

3. The polishing apparatus according to claim 1, wherein the second sensor is an eddy current sensor and the output of the second signal is equal to or less than a saturation level when the film thickness of the film falls below the predetermined film thickness.

4. The polishing apparatus according to claim 3, wherein the first sensor is an eddy current sensor and the first sensor is smaller in size than the second sensor.

5. The polishing apparatus according to claim 3, wherein a magnetic field generated by the second sensor is stronger than the magnetic field generated by the first sensor.

6. The polishing apparatus according to claim 1, wherein the polishing apparatus comprises a plurality of the first sensors and/or a plurality of the second sensors.

7. The polishing apparatus according to claim 1, wherein the first sensor and the second sensor are arranged on a circumference of substantially one circle inside the polishing table.

8. The polishing apparatus according to claim 7, wherein the number of the first sensors is plural, the first sensors being arranged at mutually and substantially equal intervals on the circumference, and/or
the number of the second sensors is plural, the second sensors being arranged mutually and substantially at equal intervals on the circumference.

9. The polishing apparatus according to claim 8, wherein the number of the first sensors is equal to the number of the second sensors, and
the first sensors and the second sensors are alternately arranged on the circumference.

10. A polishing method comprising:
a holder pressing a substrate against a polishing pad and polishing a film provided on the substrate;
a first sensor outputting a first signal corresponding to a film thickness of the film;
a second sensor that is more sensitive than the first sensor outputting a second signal corresponding to the film thickness of the film;
before the film reaches a predetermined film thickness, a film thickness detector detecting the film thickness of the film according to the first signal and the second signal; and
when the film falls below a predetermined film thickness, the film thickness detector detecting the film thickness of the film according to the second signal.

11. The polishing method according to claim 10, the method comprising:
a controller controlling pressures inside a plurality of pressure chambers provided in the holder in accordance with the film thickness detected by the film thickness detector; and
while the pressures inside the plurality of pressure chambers are being controlled, the holder pressing the substrate against the polishing pad and polishing the film provided on the substrate.
